(19) United States
(12) Patent Application Publication
(10) Pub. No.: US 2014/0130854 A1
(43) Pub. Date: May 15, 2014

(54) PHOTOELECTRIC DEVICE AND THE MANUFACTURING METHOD THEREOF

(71) Applicant: SAMSUNG SDI CO., LTD., Yongin-si (KR)

(72) Inventors: Doo-Youl Lee, Yongin-si (KR); Sang-Jin Park, Yongin-si (KR); Yoon-Mook Kang, Yongin-si (KR); Hyoeng-Ki Kim, Yongin-si (KR); Chan-Bin Mo, Yongin-si (KR); Young-Sang Park, Yongin-si (KR); Kyoung-Jin Seo, Yongin-si (KR); Min-Sung Kim, Yongin-si (KR); Jun-Ki Hong, Yongin-si (KR); Heung-Kyoon Lim, Yongin-si (KR); Min-Chul Song, Yongin-si (KR); Sung-Chan Park, Yongin-si (KR); Dong-Seop Kim, Yongin-si (KR)

(73) Assignee: SAMSUNG SDI CO., LTD., Yongin-si (KR)

(21) Appl. No.: 13/949,147

(22) Filed: Jul. 23, 2013

Related U.S. Application Data
(60) Provisional application No. 61/725,437, filed on Nov. 12, 2012.

(51) Int. Cl. H01L 31/065

(52) U.S. Cl. CPC H01L 31/065
USPC 136/255; 438/87

(57) ABSTRACT

A photoelectric device includes: a semiconductor substrate including monocrystalline silicon and has first and second surfaces that are opposite to each other; a doping unit formed on the first surface of the semiconductor substrate; and an insulating layer that is formed between the doping unit and the second surface of the semiconductor substrate, wherein the doping unit includes: a first semiconductor layer including a first dopant doped in the monocrystalline silicon; and a second semiconductor layer including a second dopant doped in the monocrystalline silicon.

### CROSS-REFERENCE TO RELATED APPLICATION

This application claims priority to and the benefit of U.S. Provisional Application No. 61/725,437, filed on Nov. 12, 2012 in the U.S. Patent and Trademark Office, the entire content of which is incorporated herein by reference.

### DETAILED DESCRIPTION OF THE INVENTION

1. Technical Field

One or more embodiments of the present invention relate to a photoelectric device and a method of manufacturing the same.

2. Related Art

Currently, due to problems such as exhaustion of energy resources and environmental pollution of the Earth, development of clean energy sources is accelerated. Photovoltaic energy generated using solar cells is directly transformed from sunlight and thus is regarded as a new clean energy source.

However, costs for generating photovoltaic energy that is currently industrially generated by using solar cells are high in comparison to generation of thermal energy, and power generation efficiency of the solar cells has to be increased to allow broad application fields of the solar cells. Surface recombination loss and reduction of defects of an emitter and a base that separate and collect carriers generated by light absorption are among the ways to increase power generation efficiency.

### DISCLOSURE OF THE INVENTION

### Technical Goal of the Invention

One or more embodiments of the present invention include a photoelectric device in which carrier recombination loss due to defects of a semiconductor substrate is reduced, and an open-circuit voltage is increased.

One or more embodiments of the present invention include a photoelectric device in which an emitter and a base, which separate and collect carriers, are formed of monocrystalline silicon like a semiconductor substrate to thereby increase carrier collecting efficiency and photoelectric conversion efficiency.

### Means for Achieving Technical Goal

According to one or more embodiments of the present invention, a photoelectric device includes: a semiconductor substrate that is formed of monocrystalline silicon and has first and second surfaces that are opposite to each other; a doping unit formed in the first surface of the semiconductor substrate; and an insulating layer that is formed between the doping unit and the second surface of the semiconductor substrate, wherein the doping unit includes: a first semiconductor layer including a first dopant doped in the monocrystalline silicon; and a second semiconductor layer including a second dopant doped in the monocrystalline silicon.

For example, the first and second semiconductor layers may have opposite conductivity types, and be alternately arranged in the first surface of the semiconductor substrate.

For example, the insulating layer may be formed by performing ion implantation on the first surface of the semiconductor substrate.

For example, the insulating layer may be a silicon oxide layer that is formed by oxygen ions that are implanted into the first surface of the semiconductor substrate.

For example, the first and second semiconductor layers may be insulated from each other via a trench.

For example, the trench may be formed to sequentially pass through the first surface of the semiconductor substrate, the doping unit, and the insulating layer.

For example, a trench insulating layer may be formed along a surface of the semiconductor substrate that is exposed by the trench.

According to one or more embodiments of the present invention, a method of manufacturing a photoelectric device includes: providing a semiconductor substrate that is formed of monocrystalline silicon and has first and second surfaces that are opposite to each other; forming an insulating layer between the first and second surfaces of the semiconductor substrate by ion implantation; and forming a doping unit between the first surface of the semiconductor substrate and the insulating layer, wherein the doping unit includes a first semiconductor layer including a first dopant doped in the monocrystalline silicon and a second semiconductor layer including a second dopant doped in the monocrystalline silicon.

For example, the insulating layer may be a silicon oxide layer that is formed by oxygen ions implanted into the first surface of the semiconductor substrate.

For example, the first and second semiconductor layers may have opposite conductivity types, and be alternately arranged in the first surface of the semiconductor substrate.

For example, the method may further include, after the forming of a doping unit, forming a trench between the first and second semiconductor layers.

For example, the trench may be formed to sequentially pass through the first surface of the semiconductor substrate, the doping unit, and the insulating layer.

For example, the method may further include forming a trench insulating layer along a surface of the semiconductor substrate that is exposed by the trench.

For example, the forming of a doping unit may include: forming a first doping material layer on the first surface of the semiconductor substrate; patterning the first doping material layer to correspond to an area in which the first semiconductor layer is to be formed, by removing a portion of the first doping material layer by etching; forming a second doping material layer on the first surface of the semiconductor substrate; and diffusing dopants of the first and second doping material layers into the semiconductor substrate by drive-in.

### Effect of the Invention

As described above, according to the one or more of the above embodiments of the present invention, a photoelectric device in which carrier recombination loss due to defects of a semiconductor substrate is reduced and an open-circuit voltage is increased may be provided. In particular, according to the embodiments of the present invention, an emitter and a base which separate and collect carriers are formed of monocrystalline silicon like a semiconductor substrate, and thus, carrier collecting efficiency may be increased, and photoelectric conversion efficiency may be improved.

### BRIEF DESCRIPTION OF THE DRAWINGS

FIG. 1 illustrates a photoelectric device according to an embodiment of the present invention;

FIG. 2 illustrates a photoelectric device according to a comparative example of the present invention;

FIGS. 3A through 3C illustrate a method of manufacturing the photoelectric device of FIG. 2 according to the comparative example; and

FIGS. 4A through 4L illustrate a method of manufacturing a photoelectric device according to an embodiment of the present invention.

### DESCRIPTION OF EMBODIMENT

Reference will now be made in detail to embodiments, examples of which are illustrated in the accompanying drawings, wherein like reference numerals refer to the like elements throughout.

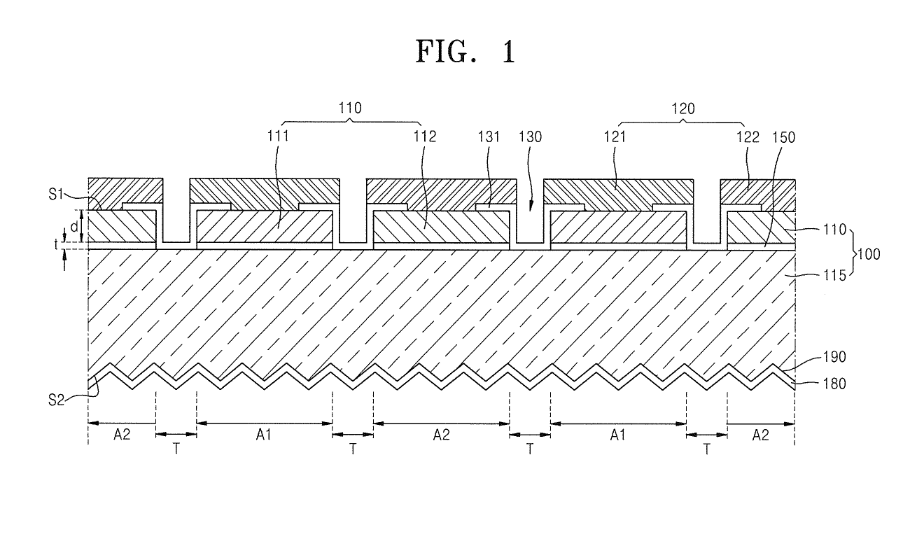

FIG. 1 illustrates a photoelectric device according to an embodiment of the present invention. Referring to FIG. 1, the photoelectric device includes a semiconductor substrate 100, first and second semiconductor layers 111 and 112 formed in the semiconductor substrate 100, and first and second electrodes 121 and 122 that are electrically connected to the first and second semiconductor layers 111 and 112. For example, a plurality of the first and second semiconductor layers 111 and 112 may be alternately arranged along a first surface S1 of the semiconductor substrate 100. The first and second semiconductor layers 111 and 112 form a doping unit 110 of the semiconductor substrate 100. The first and second semiconductor layers 111 and 112, which are adjacent to each other and have opposite conductivity types, may not contact each other but instead can be insulated from each other through a trench 130.

Referring to FIG. 1, a first area A1 and a second area A2 are areas where the first and second semiconductor layers 111 and 112 are formed. In addition, a trench area T in which the trench 130 is formed is located between the first and second areas A1 and A2.

The trench 130 is formed to insulate the first and second semiconductor layers 111 and 112 having opposite conductivity types, from each other, and may be formed, for example, from the first surface S1 of the semiconductor substrate 100 to about a depth of the doping unit 110. According to an embodiment of the present invention, the trench 130 may be formed to about a depth of an insulating layer 150 formed at a depth d of the semiconductor substrate 100 to thereby provide insulation of the first and second semiconductor layers 111 and 112. A trench insulating layer 131 may be formed along a surface of the semiconductor substrate 100 exposed through the trench 130. The trench insulating layer 131 may passivate the exposed surface of the semiconductor substrate 100 so as to reduce surface recombination loss.

The semiconductor substrate 100 may include the first surface S1 and a second surface S2 that is opposite to the first surface S1. For example, a back-contact including electrodes 120 of both an emitter and a base may be formed in the first surface S1, and the second surface S2 which does not include a structure of the electrodes 120 may function as a light-receiving surface, thereby increasing effective incident light and reducing light loss. For example, by forming a back-contact where the electrode 120 is not formed, on the light-receiving surface of the semiconductor substrate 100 (i.e., the second surface S2), light loss due to the electrodes 120 may be reduced and high output may be obtained compared to conventional solar cells in which the electrode 120 is formed on a light-receiving surface.

For example, by receiving light through the second surface S2, photogenerated carriers may be produced in the semiconductor substrate 100. The photogenerated carriers (hereinafter, “carriers”) refer to holes and electrons that are produced as a result of light absorption by the semiconductor substrate 100. The semiconductor substrate 100 may be formed of a monocrystalline silicon substrate having an n-type or p-type conductivity type. For example, according to an embodiment of the present invention, the semiconductor substrate 100 may be formed of an n-type monocrystalline silicon substrate. A texture structure 190 including uneven patterns may be formed on the second surface S2 of the semiconductor substrate 100. The texture structure 190 may have an uneven surface including a plurality of minute protrusions and may reduce reflectivity of incident light.

A passivation layer 180 may be formed on the textured second surface S2 of the semiconductor substrate 100. The passivation layer 180 may prevent recombination of carriers that are produced in the semiconductor substrate 100, thereby increasing carrier collecting efficiency.

The first and second semiconductor layers 111 and 112 which have reverse conductivity types with respect to each other may be formed on the first surface S1 of the semiconductor substrate 100. For example, a plurality of the first and second semiconductor layers 111 and 112 may be alternately arranged along the first surface S1 of the semiconductor substrate 100. The first and second semiconductor layers 111 and 112 may respectively function as an emitter and a base that separate and collect carriers produced in the semiconductor substrate 100. The first and second semiconductor layers 111 and 112 may be selectively formed in the first and second areas A1 and A2 of the first surface S1 of the semiconductor substrate 100.

The first semiconductor layer 111 may be formed of monocrystalline silicon, for example, monocrystalline silicon having the same lattice constant as the semiconductor substrate 100. The first semiconductor layer 111 may be formed by implanting a p-type or n-type dopant into the semiconductor substrate 100. For example, the first semiconductor layer 111 may be doped with a p-type which is opposite to the n-type semiconductor substrate 100, and may function as an emitter that collects minority carriers (e.g., holes) from the n-type semiconductor substrate 100.

The second semiconductor layer 112 may be formed of monocrystalline silicon, for example, monocrystalline silicon having the same lattice constant as the semiconductor substrate 100. The second semiconductor layer 112 may be formed by implanting a p-type or n-type dopant into the semiconductor substrate 100. For example, the second semiconductor layer 112 having an n-type conductivity type like the n-type semiconductor substrate 100 may be formed, and may function as a base that collects majority carriers (e.g., electrons) from the n-type semiconductor substrate 100.

The first and second semiconductor layers 111 and 112 may be separated by the trench 130 so as not to contact each other and to be electrically insulated from each other. That is, the trench 130 may be formed between the first and second semiconductor layers 111 and 112, and may insulate the first and second semiconductor layers 111 and 112 from each other. The trench insulating layer 131 may be formed on the surface of the semiconductor substrate 100 that is exposed by the trench 130. The trench insulating layer 131 may passivate the surface of the semiconductor substrate 100 that is exposed by the trench 130.

The first and second semiconductor layers 111 and 112 form the doping unit 110 of the semiconductor substrate 100. The doping unit 110 of the semiconductor substrate 100 may be formed in a surface of the semiconductor substrate 100 and of monocrystalline silicon having the same lattice constant as a main body 115 of the semiconductor substrate 100. As the first and second semiconductor layers 111 and 112 which separate and collect photo-generated carriers, are formed of monocrystalline silicon, defects of the first and second semiconductor layers 111 and 112 may be minimized, and loss due to defects such as carrier trapping may be reduced.

According to an embodiment of the present invention, the doping unit 110 is a portion of the semiconductor substrate 100 and is formed of monocrystalline silicon. For example, the doping unit 110 may be not an epitaxial layer that is epitaxially grown on the surface of the semiconductor substrate 100 but be formed as a portion of the monocrystalline semiconductor substrate 100. As will be described later, the insulating layer 150 is formed between the doping unit 110 and the main body 115 of the semiconductor substrate 100, and the insulating layer 150 may be formed at a depth d from the surface of the semiconductor substrate 100 by ion implantation, and the doping unit 110 including the first and second semiconductor layers 111 and 112 may be formed by diffusing p-type or n-type dopants into the surface of the semiconductor substrate 100.

For example, the doping unit 110 may be formed on the first surface S1 of the semiconductor substrate 100, and the insulating layer 150 may be formed between the doping unit 110 and the second surface S2 of the semiconductor substrate 100. The insulating layer 150 may passivate the semiconductor substrate 100 so as to reduce carrier recombination loss due to defects of the semiconductor substrate 100 and improve carrier collecting efficiency, and accordingly, an open-circuit voltage of the photoelectric device may be increased.

For example, while being formed or through passivation of the semiconductor substrate 100, the insulating layer 150 may spontaneously have characteristics of positive fixed charges or negative fixed charges. For example, the insulating layer 150 may have characteristics of positive fixed charges, and prevent access of holes which are minority carriers of the n-type semiconductor substrate 100, thereby increasing the life span of the minority carriers. For example, the insulating layer 150 may be formed of a silicon oxide layer or a silicon nitride layer, but the embodiments of the present invention are not limited thereto.

According to an embodiment of the present invention, the insulating layer 150 may be formed by ion implantation, and by this ion implantation, the insulating layer 150 may be formed at a depth d between the first surface S1 and the second surface S2 of the semiconductor substrate 100. For example, the insulating layer 150 may be formed of a silicon oxide layer that is formed by ion implantation of oxygen ions.

For example, in the ion implantation, ions may be penetrated through from the surface of the semiconductor substrate 100 to a desire depth by controlling a projection range which is a linear distance that ions are projected from the surface of the semiconductor substrate 100, and the depth d or a thickness t of the insulating layer 150 may be precisely adjusted. Also, by controlling the projection range, a profile of an ion concentration according to a depth direction of the semiconductor substrate 100 may be adjusted. The projection range may be adjusted according to the amount of energy that accelerates ion beams during ion implantation. Also, by controlling an ion dose that is implanted during the ion implantation, a composition of the insulating layer 150 or a profile of an ion concentration may be precisely adjusted.

By controlling process conditions of ion implantation such as the projection range and ion dose, the thickness t of the insulating layer 150 may be precisely adjusted, and the insulating layer 150 having uniform insulating characteristics over the whole semiconductor substrate 100 may be formed, and tunneling of carriers through the insulating layer 150 may also be maintained substantially uniformly.

According to an embodiment of the present invention, the insulating layer 150 may have the thickness t of about 5˜30 Å. If the insulating layer 150 is thicker than the above range, tunneling of carriers is difficult, and thus collection of carriers by using the first and second semiconductor layers 111 and 112 is also difficult; if the insulating layer 150 is thinner than the above range, the insulating layer 150 may not substantially perform the function of passivation, and this makes it difficult to increase an open-circuit voltage. According to an embodiment of the present invention, the insulating layer 150 may be formed at a depth d of about 2000 Å to about 3000 Å from the surface of the semiconductor substrate 100.

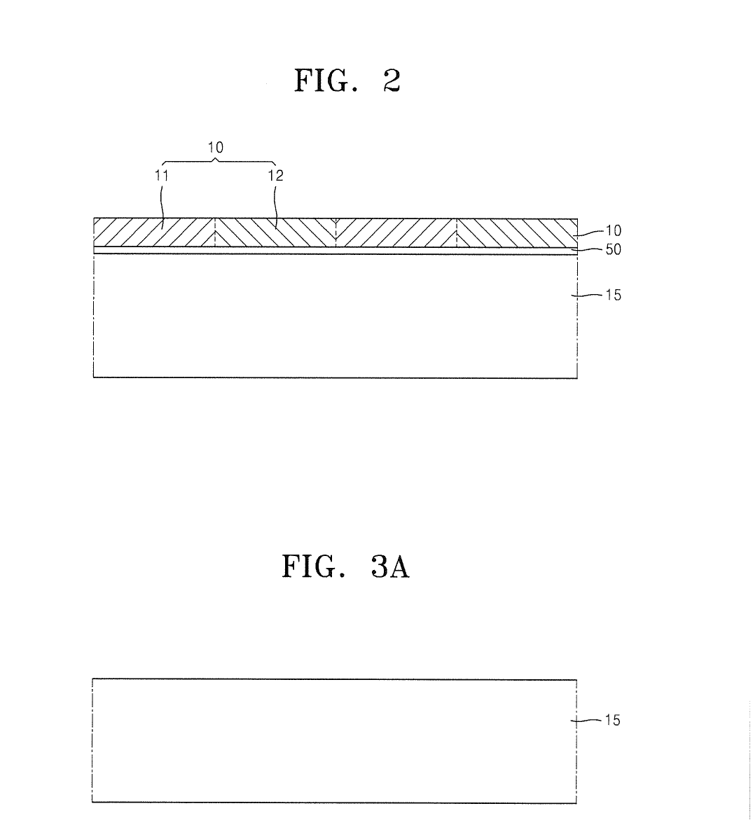

FIG. 2 illustrates a photoelectric device according to a comparative example of the present invention. Referring to FIG. 2, a doping unit 10 is formed on a semiconductor substrate 15, and an insulating layer 50 is formed between the semiconductor substrate 15 and the doping unit 10. The doping unit 10 is formed of polycrystalline silicon or amorphous silicon.

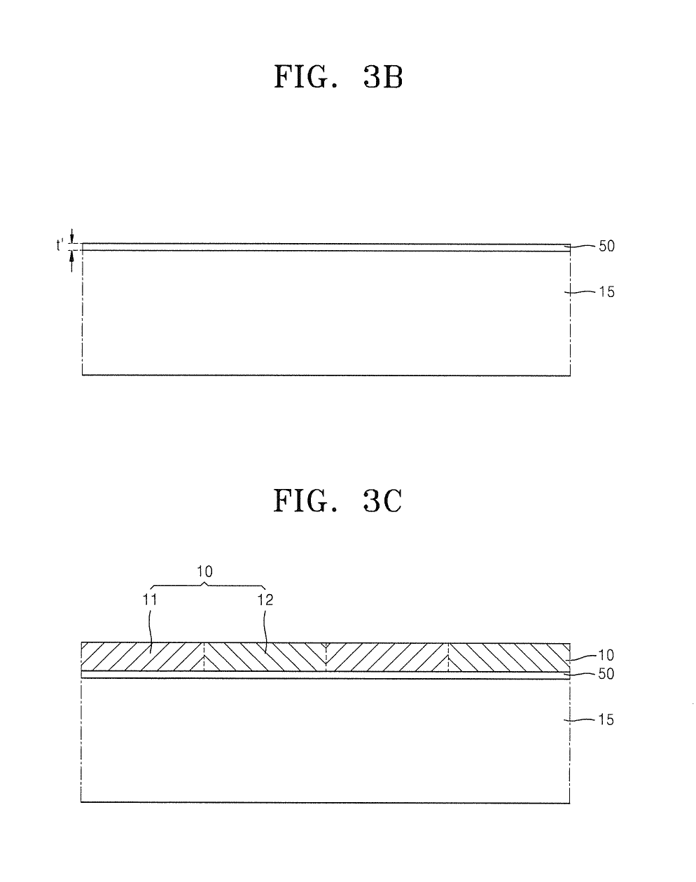

FIGS. 3A through 3C illustrate a method of manufacturing the photoelectric device of FIG. 2 according to the comparative example. Referring to FIGS. 3A through 3C, the insulating layer 50 having a predetermined thickness t is formed on the semiconductor substrate 15 by using a thermal oxidizing operation (see FIG. 3B), and the doping unit 10 including first and second semiconductor layers 11 and 12 having opposite conductivity types are formed on the insulating layer 50 (see FIG. 3C). As the first and second semiconductor layers 11 and 12 are formed on the insulating layer 50 that covers the semiconductor substrate 15, they may not be formed of monocrystalline silicon, but rather of polycrystalline silicon or amorphous silicon by using a deposition method such as a chemical vapor deposition (CVD) method. However, polycrystalline silicon or amorphous silicon includes various defects such as lattice defects of crystals. For example, carrier recombination loss and a decrease in photoelectric conversion efficiency may be caused.

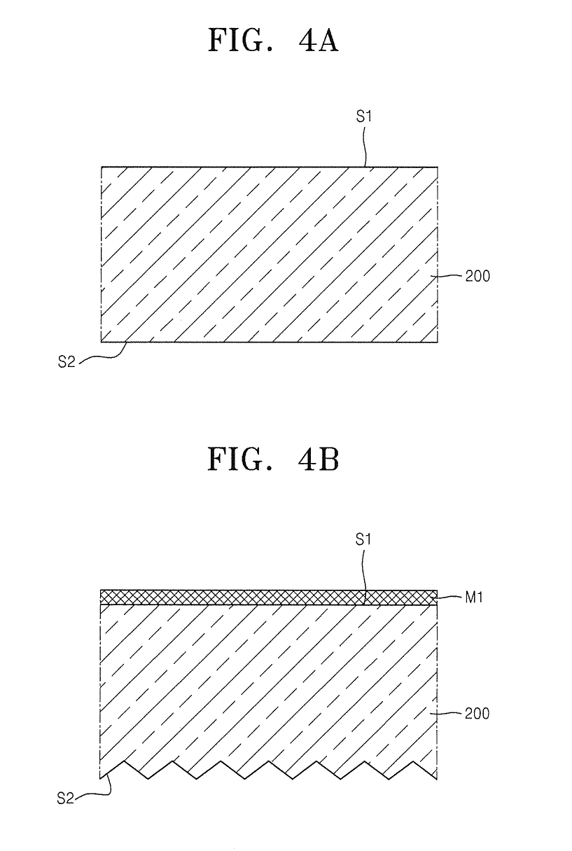

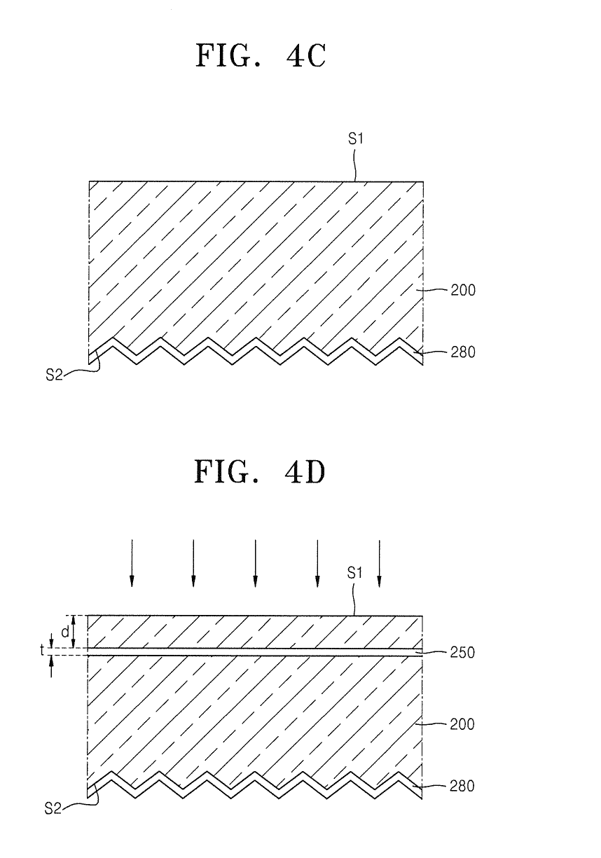

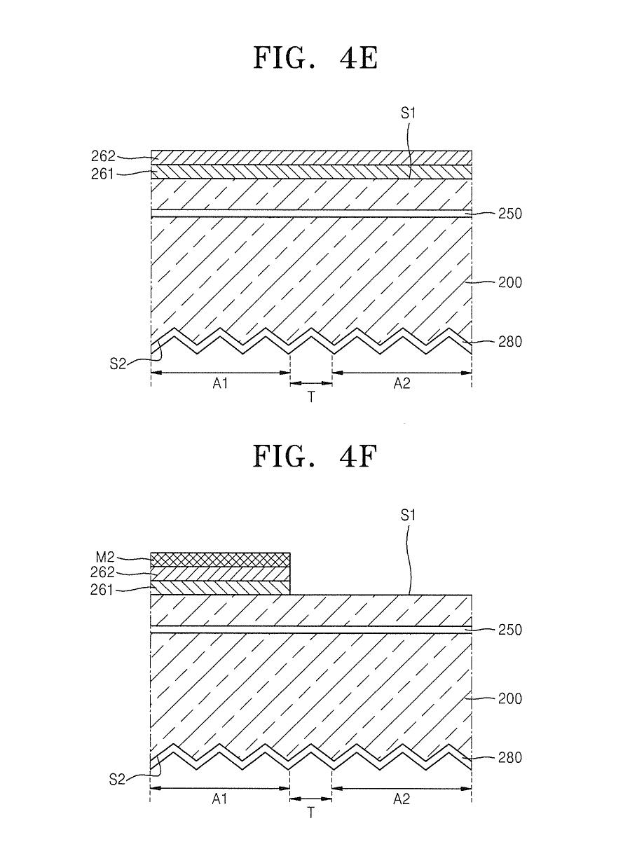

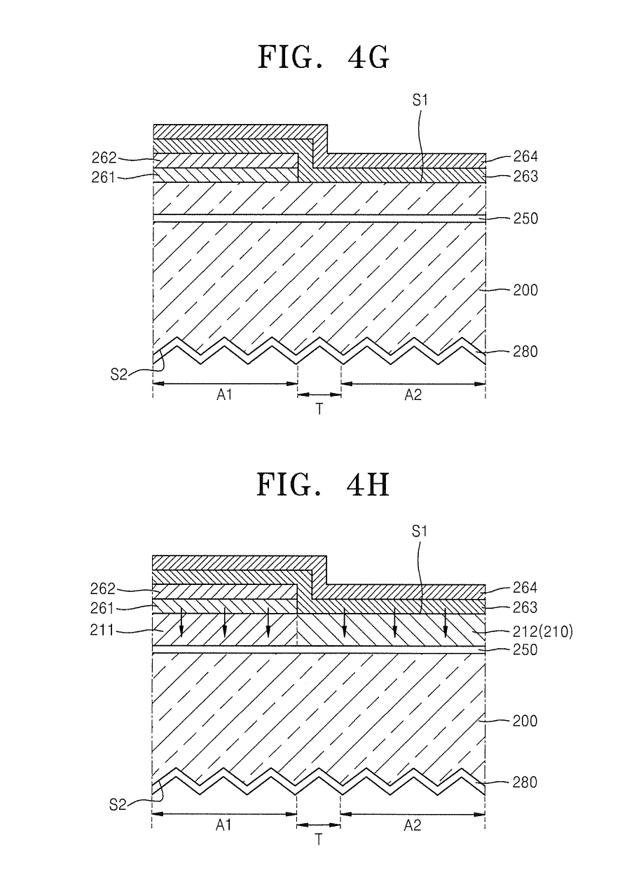

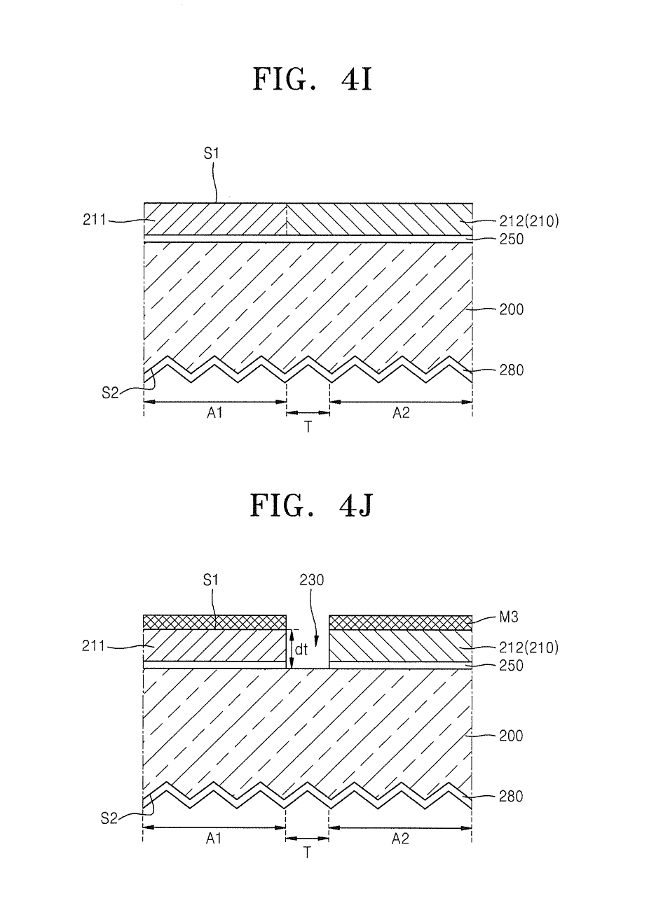

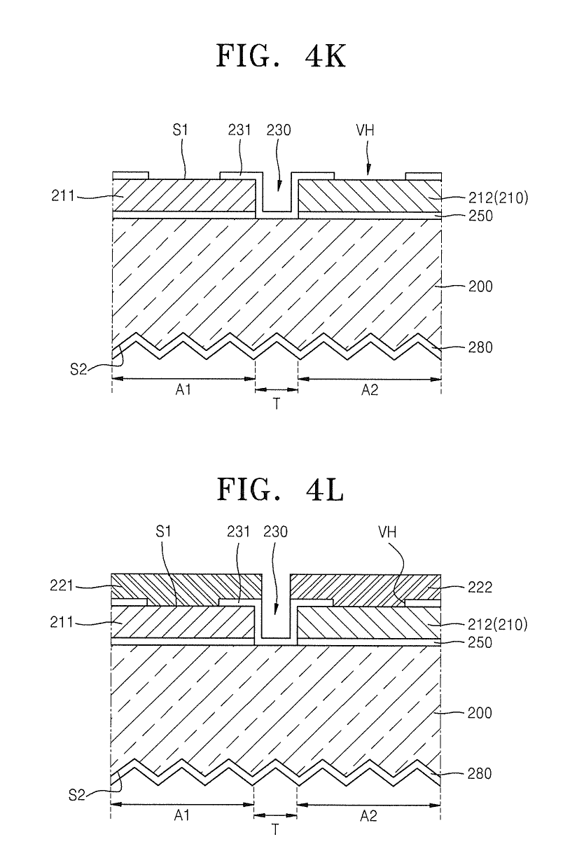

Hereinafter, a method of manufacturing a photoelectric device according to an embodiment of the present invention will be described with reference to FIGS. 4A through 4L.

First, as illustrated in FIG. 4A, a semiconductor substrate 200 is provided. For example, the semiconductor substrate 200 may be formed using an n-type or p-type monocrystalline silicon wafer. For example, to remove physical or chemical impurities attached on a surface of the semiconductor substrate 200, a cleansing operation using an acid solution or an alkali solution may be performed.

Next, as illustrated in FIG. 4B, a mask M1 is formed on a first surface S1 of the semiconductor substrate 200. The mask M1 functions as an etch stopper layer that protects the first surface S1 of the semiconductor substrate 200 when performing texturing for forming uneven patterns in a second surface S2 of the semiconductor substrate 200.

Next, as illustrated in FIG. 4B, texturing is performed on the second surface S2 of the semiconductor substrate 200. The second surface S2 of the semiconductor substrate 200 is etched by using the mask M1 formed on the first surface S1 of the semiconductor substrate 200. For example, anisotropic etching in which an alkali solution is used may be performed with respect to the semiconductor substrate 200 so as to form a texture structure of uneven patterns in the second surface S2 of the semiconductor substrate 200.

Next, as illustrated in FIG. 4C, a passivation layer 280 may be formed on the second surface S2 of the semiconductor substrate 200. The passivation layer 280 may prevent surface recombination of carriers that are produced in the semiconductor substrate 200 to thereby improve carrier collecting efficiency. For example, the passivation layer 280 may be formed of an intrinsic semiconductor layer, a doped semiconductor layer, a silicon oxide layer (SiOx), or a silicon nitride layer (SiNx).

Next, as illustrated in FIG. 4D, an insulating layer 250 is formed on the semiconductor substrate 200 by ion implantation. For example, the ion implantation may be performed with respect to the first surface S1 of the semiconductor substrate 200, and the insulating layer 250 may be formed over the entire area of the semiconductor substrate 200. For example, the insulating layer 250 may be formed of a silicon oxide layer by ion implantation of oxygen ions.

For example, when performing the ion implantation, by controlling process conditions such as a projection range and an ion dose, ions may be penetrated through from the surface of the semiconductor substrate 200 to a desired depth, and a depth d at which the insulating layer 250 is formed and a thickness t of the insulating layer 250 may be precisely controlled. In detail, according to an embodiment of the present invention, the insulating layer 250 may be formed at a depth d of about 2000 μm to 3000 Å μm from the surface of the semiconductor substrate 200 and may have a thickness t of about 5˜30 Å.

Next, as illustrated in FIG. 4E, a first doping material layer 261 is formed on the first surface S1 of the semiconductor substrate 200. For example, the first doping material layer 261 may be formed over the entire area of the semiconductor substrate 200 including first and second areas A1 and A2 and a trench area T.

The first doping material layer 261 may be formed of a silicon oxide layer including a p-type or n-type dopant, and may include, for example, a p-type dopant which has a reverse conductivity type to the n-type semiconductor substrate 200. The first doping material layer 261 may be formed using a CVD method, and may be formed of, for example, phosphorous silicate glass (PSG). As will be described later, the dopant of the first doping material layer 261 diffuses toward the semiconductor substrate 200 by drive-in, and a first semiconductor layer 211 is formed in a surface of the semiconductor substrate 200.

Next, as illustrated in FIG. 4E, a first diffusion barrier layer 262 may be formed on the first doping material layer 261. The first diffusion barrier layer 262 may prevent diffusion of the dopant of the first doping material layer 261 in a reverse direction during drive-in, which will be described later. For example, a silicon oxide layer not including a p-type or n-type dopant may be applied as the first diffusion barrier layer 262.

Next, as illustrated in FIG. 4F, the first doping material layer 261 and the first diffusion barrier layer 262 are patterned. That is, an area except the first area A1 may be removed, and the first doping material layer 261 and the first diffusion barrier layer 262 formed in the second area A2 and the trench area T may be removed by etching. In detail, a mask M2 may be applied on the first area A1, and portions exposed through the mask M2 may be removed. When etching is completed, the used mask M2 is removed.

Next, as illustrated in FIG. 4G, a second doping material layer 263 is formed on the semiconductor substrate 200. The second doping material layer 263 may be formed of a silicon oxide layer including a p-type or n-type dopant, and may include, for example, an n-type dopant which has the same conductivity type as the n-type semiconductor substrate 200. The second doping material layer 263 may be formed using a CVD method, and may be formed of, for example, boron silicate glass (BSG). As will be described later, the dopant of the second doping material layer 263 diffuses to the semiconductor substrate 200 by drive-in, and a second semiconductor layer 212 is formed in the surface of the semiconductor substrate 200. The second doping material layer 263 may be formed over the entire area of the semiconductor substrate 200 including the second area A2.

Next, as illustrated in FIG. 4G, a second diffusion barrier layer 264 may be formed on the second doping material layer 263. The second diffusion barrier layer 264 may prevent diffusion of the dopant of the second doping material layer 263 in a reverse direction during drive-in, which will be described later. For example, a silicon oxide layer not including a p-type or n-type dopant may be applied as the second diffusion barrier layer 264.

Next, as illustrated in FIG. 4H, in order that the dopants of the first and second material layers 261 and 263 formed on the semiconductor substrate 200 may quickly diffuse into the semiconductor substrate 200, drive-in is performed. During the drive-in, the semiconductor substrate 200 is maintained at a high temperature without additional implantation of a doping material. For example, the dopant of the first doping material 261 diffuses into the first area A1 of the semiconductor substrate 200, and the first semiconductor layer 211 is formed in the first area A1. In addition, the dopant of the second doping material layer 263 diffuses into the second area A2 of the semiconductor substrate 200, and the second semiconductor layer 212 is formed in the second area A2. The first and second semiconductor layers 211 and 212 may form a doping unit 210 of the semiconductor substrate 200.

Next, as illustrated in FIG. 4I, etch-back for removing the first and second doping material layers 261 and 263 and the first and second diffusion barrier layers 262 and 264 may be performed. The first and second doping material layers 261 and 263 include a precipitate of metal impurities contained in the semiconductor substrate 200, and thus, by removing the precipitate, the effect of gettering of removing the impurities may be provided. During the etch-back, the first and second doping material layers 261 and 263 and the first and second diffusion barrier layers 262 and 264 may be removed either simultaneously or sequentially.

Next, as illustrated in FIG. 4J, a trench 230 is formed between the first and second semiconductor layers 211 and 212 such that the first and second semiconductor layers 211 and 212 do not contact each other, but instead are insulated from each other. The trench 230 is formed at a depth dt from the first surface S1 of the semiconductor substrate 200; the trench 230 is formed at least to a depth generally corresponding to the doping unit 210 of the semiconductor substrate 200 to thereby separate the first and second semiconductor layers 211 and 212. According to an embodiment of the present invention, the trench 230 is formed to the depth dt to pass through the doping unit 210 and the insulating layer 250 of the semiconductor substrate 200, thereby providing insulation between the first and second semiconductor layers 211 and 212. In order to control the depth dt of the trench 230, a process time may be adjusted in consideration of an etching speed according to an etchant, or an additional etching stopper layer may be formed in the semiconductor substrate 200 by ion implantation or the like.

For example, the trench 230 is formed to a depth dt generally corresponding to the doping unit 210 and the insulating layer 250 by forming a mask M3 on the first and second areas A1 and A2 of the semiconductor substrate 200 and etching portions of the doping unit 210 and the insulating layer 250 corresponding to an area between the first and second areas A1 and A2 that is exposed through the mask M3, to the depth dt of the semiconductor substrate 200. For example, the trench 230 may be formed by sequentially removing the portions of the doping unit 210 and the insulating layer 250 between the first area A1 and the second area A2. Accordingly, the first and second semiconductor layers 211 and 212 of the first and second areas A1 and A2 may be separated and electrically insulated from each other. When etching is completed, the used etching mask M3 is removed.

Next, as illustrated in FIG. 4K, a trench insulating layer 231 may be formed along a surface of the semiconductor substrate 200 that is exposed through the trench 230. For example, the trench insulating layer 231 may passivate the semiconductor substrate 200, remove surface defects of the semiconductor substrate 200, and reduce loss due to recombination of carriers. For example, the trench insulating layer 231 may be formed at least in the trench area T to cover the trench surface, and may also be extended up to portions of the first and second areas A1 and A2 that are adjacent to the trench area T.

According to an embodiment of the present invention, the trench insulating layer 231 may be formed on the entire area of the first surface S1 of the semiconductor substrate 200 including the first and second areas A1 and A2 and the trench area T, and a via hole VH through which the first and second semiconductor layers 211 and 213 and the first and second electrodes 221 and 222 are electrically connected to each other may be formed by removing a portion of the first and second areas A1 and A2 of the trench insulating layer 231 that is formed over the entire area of the semiconductor substrate 200. For example, the trench insulating layer 231 may be formed of a silicon oxide layer SiOx or a silicon nitride layer SiNx and by using thermal oxidization or deposition.

Next, as illustrated in FIG. 4L, first and second electrodes 221 and 222 whereby collected carriers are withdrawn to the outside may be formed on the first and second semiconductor layers 211 and 212, respectively. The first and second electrodes 221 and 222 may include a metal such as silver (Ag), aluminum (Al), copper (Cu), or nickel (Ni). For example, the first and second electrodes 221 and 222 may be formed by pattern-printing a metal paste by screen printing and thermally curing the patterned metal paste. For example, the first and second electrodes 221 and 222 may be respectively electrically connected to the first and second semiconductor layers 211 and 212 via the via hole VH.

According to another embodiment of the present invention, a transparent conductive oxide (TCO) layer may be located between the first and second semiconductor layers 211 and 212 and the first and second electrodes 221 and 222.

It should be understood that the exemplary embodiments described therein should be considered in a descriptive sense only and not for purposes of limitation. Descriptions of features or aspects within each embodiment should typically be considered as available for other similar features or aspects in other embodiments.

### EXPLANATION OF REFERENCE NUMERALS DESIGNATING THE MAJOR ELEMENTS OF THE DRAWINGS

| | |
|---|---|
| 100, 200: semiconductor substrate | 110, 210: doping unit |
| 111, 211: first semiconductor layer | 112, 212: second semiconductor |
| 120: electrode | layer |
| 122, 222: second electrode | 121, 221: first electrode |
| 131, 231: trench insulating layer | 130, 230: trench |
| 180, 280: passivation layer | 150, 250: insulating layer |
| 261: first doping material layer | 190: texture structure |
| 263: second doping material layer | 262 : first diffusion barrier layer |
| A1: first area | 264: second diffusion barrier layer |
| T: trench area | A2: second area |
| S1: first surface of semiconductor | M1, M2, M3: mask |
| substrate | |
| S2: second surface of | |
| semiconductor substrate | |
| VH: via hole | |

What is claimed is:

1. A photoelectric device comprising:
a semiconductor substrate comprising monocrystalline silicon, the semiconductor substrate having a first surface S1 and a second surface S2 substantially opposite to the first surface;
a doping unit at the first surface S1 of the semiconductor substrate, the doping unit comprising:
a first semiconductor layer comprising a first dopant doped in monocrystalline silicon; and
a second semiconductor layer comprising a second dopant doped in monocrystalline silicon; and
a first insulating layer between the doping unit and the second surface S2 of the semiconductor substrate.

2. The photoelectric device of claim 1, wherein the first semiconductor layer has a first conductivity type and wherein the second semiconductor layer has a second conductivity type different from the first conductivity type.

3. The photoelectric device of claim 1, wherein the first insulating layer comprises silicon oxide.

4. The photoelectric device of claim 1, wherein the first semiconductor layer and the second semiconductor layer are spaced from each other by a trench.

5. The photoelectric device of claim 4, wherein the trench extends sequentially through the first surface S1 of the semiconductor substrate, the doping unit, and the first insulating layer.

6. The photoelectric device of claim 4, wherein a second insulating layer extends over the trench.

7. The photoelectric device of claim 4, further comprising a first electrode electrically coupled to the first semiconductor layer and a second electrode electrically coupled to the second semiconductor layer.

8. The photoelectric device of claim 7, wherein the second insulating layer extends between the first semiconductor layer and the first electrode and between the second semiconductor layer and the second electrode.

9. The photoelectric device of claim 1, wherein the first semiconductor layer and the second semiconductor layer are alternately arranged.

10. A method of manufacturing a photoelectric device, the method comprising:
forming a semiconductor substrate comprising monocrystalline silicon, wherein the semiconductor substrate has a first surface S1 and a second surface S2 opposite to the first surface;
forming by ion implantation a first insulation layer between the first surface S1 and the second surface S2 of the semiconductor substrate; and
forming a doping unit between the first surface of the semiconductor substrate and the first insulating layer, wherein the doping unit comprises:
a first semiconductor layer doped in monocrystalline silicon; and
a second semiconductor layer doped in monocrystalline silicon.

11. The method of claim 10, wherein the first insulation layer is formed by ion implantation of oxygen ions to form a silicon oxide layer.

12. The method of claim 10, wherein forming the doping unit comprises:
forming a first doping material layer on the semiconductor substrate by chemical vapor deposition; and
forming a first diffusion barrier layer on the first doping material layer.

13. The method of claim 12, further comprising etching the first doping material layer and the first diffusion barrier layer.

14. The method of claim 13, further comprising forming a second doping material layer on the semiconductor substrate and forming a second diffusion barrier layer on the second doping material layer.

15. The method of claim 14, further comprising allowing the first doping material layer and the second doping material layer to diffuse to respectively form a first semiconductor layer in a first area and a second semiconductor layer in a second area.

16. The method of claim 15, further comprising forming a trench by etching the first semiconductor layer and the second semiconductor layer, wherein the trench spaces the first semiconductor layer from the second semiconductor layer.

17. The method of claim 16, wherein forming the trench further comprises etching the first insulation layer.

18. The method of claim 17, further comprising forming a second insulating layer that covers a surface of the trench and that covers the first semiconductor layer and the second semiconductor layer.

19. The method of claim 18, further comprising removing a portion of the second insulating layer that contacts the first semiconductor layer or the second semiconductor layer.

20. The method of claim 19, further comprising forming a first electrode and a second electrode respectively on the first semiconductor layer and the second semiconductor layer.
